(19) United States
(12) Patent Application Publication
(10) Pub. No.: US 2020/0080201 A1
(43) Pub. Date: Mar. 12, 2020

(54) PLASMA TREATMENT DEVICE AND METHOD FOR MANUFACTURING SEMICONDUCTOR DEVICE

(71) Applicant: TOSHIBA MEMORY CORPORATION, Tokyo (JP)

(72) Inventor: Hideaki MASUDA, Nagoya Aichi (JP)

(73) Assignee: TOSHIBA MEMORY CORPORATION, Tokyo (JP)

(21) Appl. No.: 16/290,792

(22) Filed: Mar. 1, 2019

(30) Foreign Application Priority Data
Sep. 11, 2018 (JP) 2018-169612

(51) Int. Cl. C23C 16/505; C23C 16/458; H01J 37/32; H05H 1/46; H01L 21/02; C23C 16/40

(52) U.S. Cl. CPC C23C 16/505; C23C 16/4586; H01J 37/32091; C23C 16/402; H05H 1/46; H01L 21/02274; H01J 37/32862

(57) ABSTRACT

A plasma treatment device for forming a film on a substrate using plasma enhanced chemical vapor deposition includes an upper electrode and a substrate placing table on which the substrate is to be placed and which includes a heater configured to heat the substrate and a lower electrode opposed to the upper electrode. The device additionally includes a first side surface electrode that is embedded in a side surface of the substrate placing table and is spaced from the lower electrode. A second side surface electrode that is opposed to the first side surface electrode is disposed outside the substrate placing table.

### CROSS-REFERENCE TO RELATED APPLICATIONS

This application is based upon and claims the benefit of priority from Japanese Patent Application No. 2018-169612, filed on Sep. 11, 2018, the entire contents of which are incorporated herein by reference. 1

### FIELD

Embodiments described herein relate generally to a plasma treatment device and a method for manufacturing a semiconductor device.

### BACKGROUND

In a plasma treatment device that forms a film on a substrate using plasma enhanced chemical vapor deposition, a dry cleaning treatment may be performed every time a predetermined treatment time elapses. After the dry cleaning treatment, particles may be generated from a member.

These particles may negatively affect future plasma treatments. A treatment to suppress or prevent the presence of such particles is desired.

### DESCRIPTION OF THE DRAWINGS

FIG. 1 is a longitudinal sectional view schematically showing a configuration example of a plasma treatment device according to at least one embodiment.

FIG. 2 is a cross-sectional view schematically showing a surrounding configuration of a heater pedestal of the plasma treatment device according to at least one embodiment.

FIG. 3 is a schematic diagram showing a state of a plasma treatment for a wafer in the plasma treatment device according to at least one embodiment.

FIG. 4 is a schematic diagram showing a state of a dry cleaning treatment in the plasma treatment device according to at least one embodiment.

FIG. 5 is a schematic diagram showing a state of a seasoning treatment in the plasma treatment device according to at least one embodiment.

FIG. 6 is a flowchart showing an example of a procedure of a manufacturing process for a semiconductor device in the plasma treatment device according to at least one embodiment.

FIG. 7 is a cross-sectional view schematically showing a surrounding configuration of a heater pedestal of a plasma treatment device according to a modified embodiment.

### DETAILED DESCRIPTION

Embodiments herein provide a method for manufacturing a semiconductor device, and a plasma treatment device that can prevent generation of particles after a dry cleaning treatment.

In general, according to one embodiment, a plasma treatment device for forming a film on a substrate using a plasma chemical vapor deposition method includes: an upper electrode; a substrate placing table on which the substrate is to be placed and includes a lower electrode opposed to the upper electrode and a heater configured to heat the substrate; a first side surface electrode that is embedded in a side surface of the substrate placing table and is spaced from the lower electrode; and a second side surface electrode that is opposed to the first side surface electrode and is disposed outside the substrate placing table.

Hereinafter, embodiments will be described with reference to the drawings. It should be noted that the present disclosure is not limited by the following embodiments. In addition, constituent elements in the following embodiments include those that can be easily assumed by those skilled in the art or those that are substantially the same.

### [Configuration Example of Plasma Treatment Device]

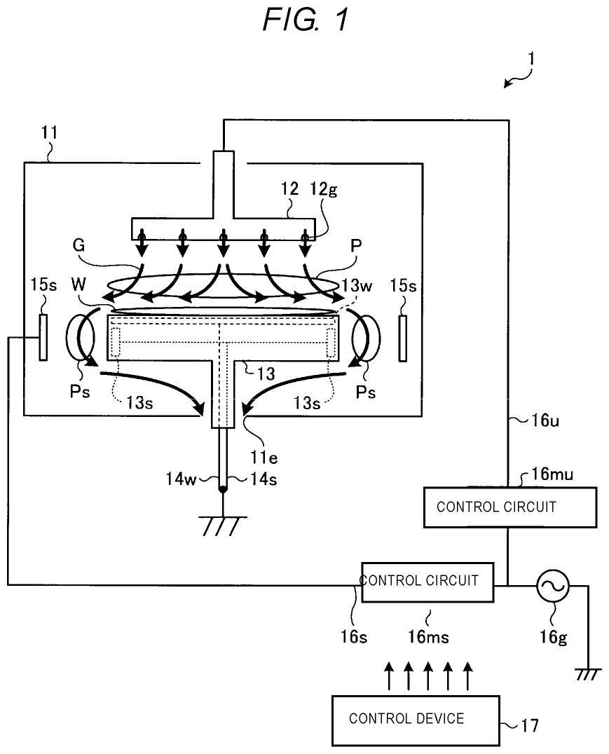

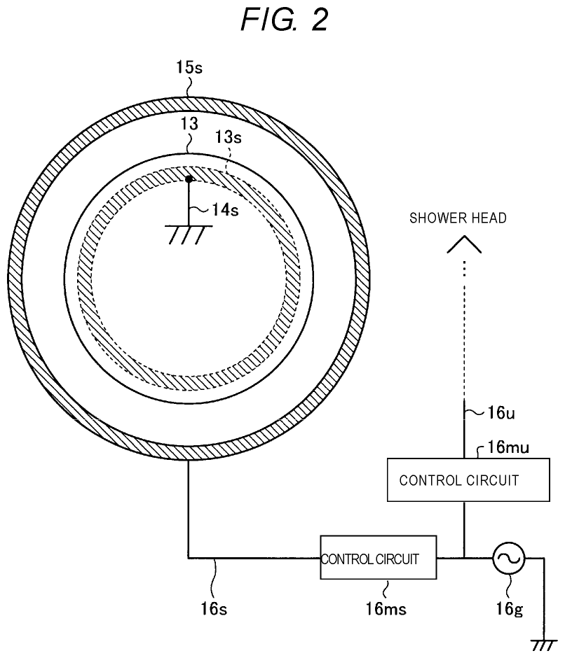

FIG. 1 is a longitudinal sectional view schematically showing a configuration example of a plasma treatment device 1 according to an embodiment. FIG. 2 is a cross-sectional view schematically showing a surrounding configuration of a heater pedestal 13 of the plasma treatment device 1 according to at least one embodiment. The plasma treatment device 1 is configured as, for example, a Plasma Chemical Vapor Deposition (PCVD) device.

As illustrated in FIG. 1, the plasma treatment device 1 includes an air-tightly formed chamber 11 as a treatment container. A gas exhaust port (opening) 11e that discharges a treatment gas or the like by a vacuum pump (not shown) is provided in a lower portion of the clamber 11.

In the vicinity of a ceiling in the chamber 11, a shower head 12 is provided as an upper electrode. The shower head 12 includes a plurality of ejection ports 12g that eject (discharge) the treatment gas or the like into the chamber 11, and functions as the upper electrode. A gas supply device (not shown) is connected to the shower head 12 via a supply pipe (not shown). The shower head 12 is mainly made of, for example, aluminum or the like.

A heater pedestal 13 is provided as a substrate placing table at a lower part of the chamber 11 and at a position that is opposed to the shower head 12. A wafer W is placed on the heater pedestal 13 as a substrate, and the placed wafer W is heated by using. The heater pedestal 13 is mainly made of a ceramic such as AlN.

A lower electrode 13w is provided in the vicinity of an upper surface of the heater pedestal 13 and inside the heater pedestal 13. The heater pedestal 13 is disposed opposed to and in parallel with the shower head 12, so that the lower electrode 13w is also opposed to and in parallel with the shower head 12 that is the upper electrode. The shower head 12 and the lower electrode 13w inside the heater pedestal 13 form a pair of parallel plate electrodes.

A side surface electrode 13s is provided in the vicinity of a side surface of the heater pedestal 13 and inside the heater pedestal 13. The side surface electrode 13s is formed in a ring shape along an inner circumference of the heater pedestal 13. FIG. 2 shows a state of the side surface electrode 13s.

A side surface electrode 15s that is disposed opposed to and in parallel with the side surface electrode 13s is provided outside the heater pedestal 13. The side surface electrode 15s is formed in a ring shape, surrounding an outer circumference of the heater pedestal 13. FIG. 2 shows a state of the side surface electrode 15s. The side surface electrode 15s and the side surface electrode 13s inside the heater pedestal 13 form a pair of parallel plate electrodes.

The shower head 12 and the side surface electrode 15s are connected to a high frequency power source 16g via a feeder line 16u and a feeder line 16s, respectively. High frequency power of a predetermined frequency is supplied from the high frequency power source 16g to the shower head 12 or the side surface electrode 15s during the plasma treatment or the like.

A control circuit 16mu that controls supply of the high frequency power to the shower head 12 is provided in the feeder line 16u. The control circuit 16mu controls the supply start and supply end of the high frequency power to the shower head 12 when the high frequency power source 16g generates the high frequency power. A control circuit 16ms that controls supply of the high frequency power to the side surface electrode 15s is provided in the feeder line 16s. The control circuit 16ms controls the supply start and supply end of high frequency power to the side surface electrode 15s when the high frequency power source 16g generates the high frequency power.

The lower electrode 13w and the side surface electrode 13s are grounded via a grounding wire 14w and a grounding wire 14s, respectively.

A control device 17 provided in the plasma treatment device 1 controls gas supply to the chamber 11 and operations of the vacuum pump, the heater pedestal 13, the high frequency power source 16g, the control circuits 16mu, 16ms and the like.

When plasma treatment is performed on the wafer W, the wafer W is placed on the heated heater pedestal 13. Further, the chamber 11 is evacuated by the vacuum pump that is connected to the gas exhaust port 11e. When a predetermined pressure is reached inside the chamber 11, a gas such as the treatment gas is supplied from the gas supply device into the chamber 11 via the ejection ports (openings) 12g of the shower head 12. The gas supplied into the chamber 11 follows paths G shown by arrows in FIG. 1 and is drawn toward the gas exhaust port 11e at the lower part of the chamber 11.

At this time, a high frequency voltage is applied to the shower head 12 that is the upper electrode with the lower electrode 13w inside the heater pedestal 13 grounded, to generate a plasma P above the upper surface of the heater pedestal 13. Accordingly, a plasma treatment is performed on the wafer W placed on the heater pedestal 13, and a layer of a predetermined material is formed, for example, on the wafer W.

In addition to or instead of this, a high frequency voltage may be applied to the side surface electrode 15s that is opposed to the side surface electrode 13s with the side surface electrode 13s inside the heater pedestal 13 grounded, to generate a plasma Ps in the vicinity of an outer circumferential surface of the heater pedestal 13.

### [Example of Treatment in Plasma Treatment Device]

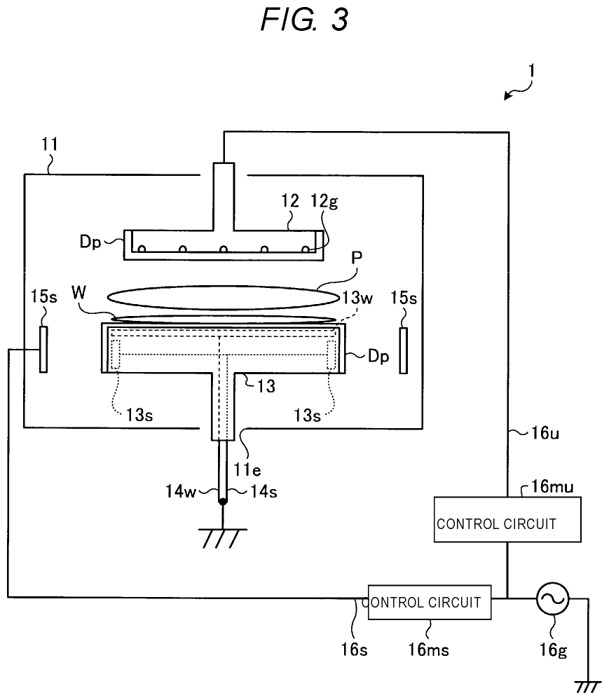

Next, examples of various treatments in the plasma treatment device 1 will be described with reference to FIGS. 3 to 5. FIG. 3 is a schematic diagram showing a state of the plasma treatment for the wafer W in the plasma treatment device 1 according to at least one embodiment.

To start the plasma treatment in the plasma treatment device 1, the shower head 12 and the heater pedestal 13 are installed inside the chamber 11. The shower head 12 and the heater pedestal 13 are new or cleaned. After the shower head 12 and heater pedestal 13 are newly installed and before the plasma treatment of the wafer W starts, a seasoning treatment is performed for a predetermined time. The seasoning treatment will be described later.

In the plasma treatment for the wafer W illustrated in FIG. 3, a plurality of wafers W are carried into the chamber 11 sequentially and subjected to the plasma treatment. In the example of FIG. 3, an insulating layer of SiO₂, SiN or the like is formed on the wafer W by such a plasma treatment. In this case, for example, a combination of a silane gas and CO₂, O₂ or the like, or a combination of the silane gas and NH₃, N₂ or the like is used as the treatment gas.

The wafer W is placed on the heater pedestal 13 that is heated to a predetermined temperature, and is heated to a plasma treatment temperature. At this time, in order to prompt film formation on the wafer W, a temperature of the shower head 12 is set to be lower than that of the heater pedestal 13.

Further, when the chamber 11 is evacuated, the treatment gas as described above is supplied into the chamber 11. Further, the high frequency power generated by the high frequency power source 16g is supplied to the shower head 12 via the control circuit 16mu. The control circuit 16ms does not supply the high frequency power to the side surface electrode 15s. Accordingly, the plasma P is formed above the heater pedestal 13 on which the wafer W is placed. Accordingly, during the plasma treatment for the wafer W, the plasma Ps in the vicinity of the side surface of the heater pedestal 13 is not generated.

When the generation of the plasma P is continued for a predetermined time, the insulating layer is formed with a predetermined thickness on the wafer W. Such a plasma treatment is repeated for the plurality of wafers W.

When the plurality of wafers W are subjected to the plasma treatment, a deposition film Dp having substantially the same component as that of the insulating layer is deposited not only on the wafers W but also on a predetermined position inside the chamber 11. FIG. 3 shows a state in which the deposition film Dp is deposited on a lower surface (a surface opposed to the heater pedestal 13) and a side surface of the shower head 12 and mainly on a side surface of the heater pedestal 13. Further, the deposition films Dp may be slightly deposited on the upper surface of the heater pedestal 13.

When the deposition film Dp on these members (e.g., the shower head 12 and the pedestal 13) becomes too thick, a stress may be generated inside the deposition film Dp and the deposition film Dp may be peeled off from the members. The peeled-off deposition film Dp serves as a particle source and contaminates the wafer W and the inside of the chamber 11. Here, after a predetermined number of wafers W are treated, the deposition film Dp is removed by dry cleaning.

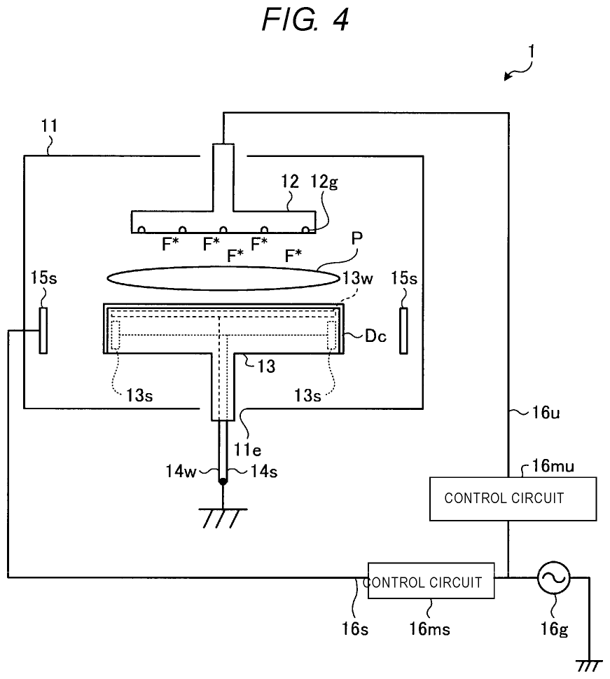

FIG. 4 is a schematic diagram showing a state of a dry cleaning treatment in the plasma treatment device 1 according to at least one embodiment.

In the dry cleaning treatment inside the chamber 11 illustrated in FIG. 4, the dry cleaning treatment is performed, for example, without placing the wafer W on the heater pedestal 13. As a cleaning gas used during the dry cleaning treatment, for example, a fluorine-based gas such as NF3 is used.

Before the start of the dry cleaning treatment, the temperature of the heater pedestal 13 is lowered to a temperature lower than that during the plasma treatment. Specifically, the temperature of the heater pedestal 13 is, for example, 500° C. or lower.

Further, the chamber 11 is evacuated and the cleaning gas as described above is supplied into the chamber 11. Further, the high frequency power generated by the high frequency power source 16g is supplied to the shower head 12 via the control circuit 16mu. Accordingly, the plasma P is generated above the heater pedestal 13.

When the generation of the plasma P is continued for a predetermined time, the deposition film Dp deposited inside the chamber 11 such as that deposited on the shower head 12 and the heater pedestal 13 is removed. After the deposition film Dp is removed, the heater pedestal 13 is exposed to a plasma of the fluorine-based gas. As a result, AlN or the like that forms a surface of the heater pedestal 13 reacts with fluorine radicals in the plasma, and for example, a fluoride Dc such as AlF is formed on the surface of the heater pedestal 13. The fluoride Dc is formed not only on the upper surface of the heater pedestal 13, but also on, for example, the side surface of the heater pedestal 13.

In principle, the side surface of the heater pedestal 13 is not directly exposed to the plasma. However, active species, such as the fluorine radicals, in the plasma may be drawn to the gas exhaust port 11e at the lower part of the chamber 11 and reach the vicinity of the side surface of the heater pedestal 13 without losing activity. Accordingly, it is considered that the fluoride Dc is formed on the side surface of the heater pedestal 13.

When the dry cleaning treatment ends, the deposition film Dp inside the chamber 11 is almost removed, and an atmosphere inside the chamber 11 is in a state greatly different from that during the plasma treatment for the wafer W. When the plasma treatment for the wafer W starts in such a state of the atmosphere, that a state of the plasma treatment changes and that a film formation characteristic varies. Particles may be generated from the members inside the chamber 11. Therefore, after the dry cleaning and before the start of the plasma treatment, the seasoning treatment is performed inside the chamber 11.

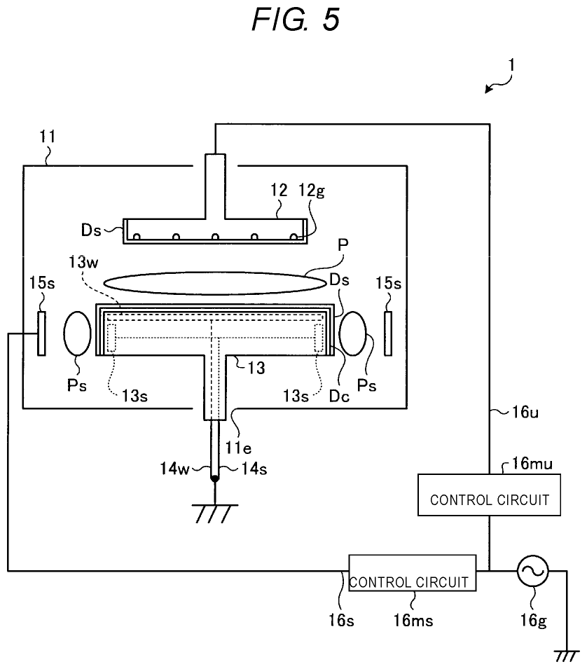

FIG. 5 is a schematic diagram showing a state of the seasoning treatment in the plasma treatment device 1 according to at least one embodiment.

In the seasoning treatment inside the chamber 11 illustrated in FIG. 5, the seasoning treatment is performed, for example, without placing the wafer W on the heater pedestal 13. As a seasoning gas used during the seasoning treatment, for example, it is preferable to use fluorine-based gas similar to that used during the plasma treatment for the wafer W. Accordingly, the atmosphere inside the chamber 11 may be restored to the atmosphere during the plasma treatment for the wafer W.

While maintaining the temperature of the heater pedestal 13 at the temperature during the dry cleaning treatment, the chamber 11 is evacuated and the seasoning gas as described above is supplied into the chamber 11. Further, the high frequency power generated by the high frequency power source 16g is supplied to the shower head 12 via the control circuit 16mu. Further, the high frequency power is also supplied to the side surface electrode 15s via the control circuit 16ms. Accordingly, the plasma P is generated above the heater pedestal 13 and the plasma Ps is generated in the vicinity of the side surface of the heater pedestal 13.

When the generated of the plasma P is continued for the predetermined time, a seasoning film Ds is formed on the lower surface and the side surface of the shower head 12 and the upper surface of the heater pedestal 13. Further, when the generation of the plasma Ps is continued for the predetermined time, the seasoning film Ds is also formed on the side surface of the heater pedestal 13. Accordingly, the surface of the shower head 12 and the surface of the heater pedestal 13 are covered with the seasoning film Ds, and the fluoride Dc on the surface of the heater pedestal 13 is also covered with the seasoning film Ds.

The seasoning film Ds has substantially the same component as that of the deposition film Dp deposited during the plasma treatment for the wafer W. However, since a time for the seasoning treatment in the chamber 11 is much shorter than a cumulative time of the plasma treatment for the wafer W, the seasoning film Ds is far thinner than the deposition film Dp and there is no risk of peeling the seasoning film Ds off. The seasoning film Ds thinly coats the members inside the chamber 11, such as the shower head 12 and the heater pedestal 13, restores the atmosphere inside the chamber 11 to the atmosphere during the plasma treatment for the wafer W and has an effect of preventing the generation of the particles from the members.

The generation times of the plasma P and Ps during which the plasma P and Ps are generated by supplying the high frequency power to the shower head 12 and the side surface electrode 15s may be changed variously according to the generation speed of the seasoning film Ds on the upper surface and the side surface of the heater pedestal 13. The generation times of the plasma P and Ps may be the same or different. When the generation times of the plasma P and Ps are different, the generation of the plasma P and the generation of the plasma Ps may start at the same time point and end at different time points; the generation of the plasma P and the generation of the plasma Ps may start at different time points and end at the same time point; or the generation of the plasma P and the generation of the plasma Ps may start at different time points and end at different time points.

After the seasoning treatment ends, the temperature of the heater pedestal 13 is raised to the temperature during the plasma treatment, and the plasma treatment for the wafer W is restarted in the plasma treatment device 1. Then, after a cycle of the plasma treatment, the dry cleaning treatment and the seasoning treatment is repeated for a predetermined number of times, the shower head 12 and the heater pedestal 13 are taken out from the chamber 11 and cleaned (wet cleaning) using a solvent or the like.

### [Example of Manufacturing Process for Semiconductor Device]

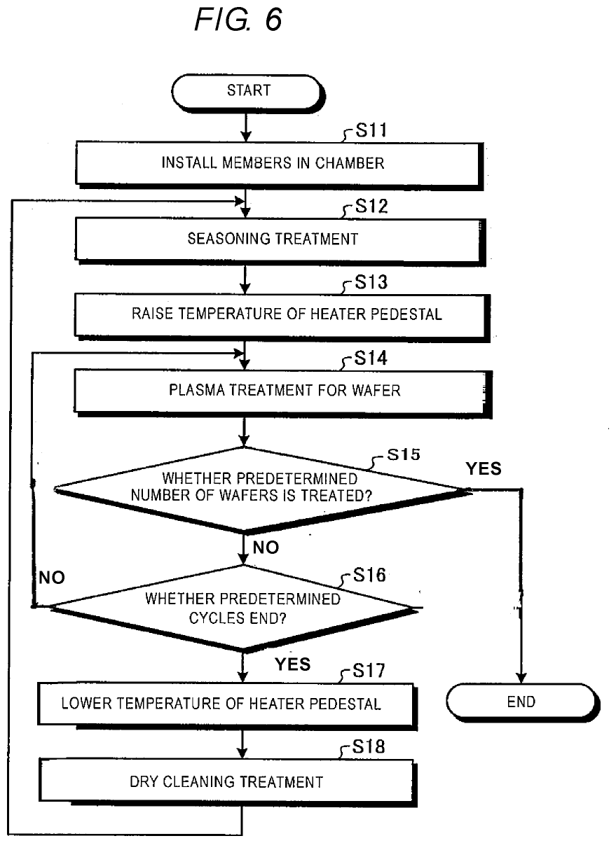

Next, with reference to FIG. 6, an example of a process as a manufacturing process for a semiconductor device in the plasma treatment device 1 will be described. FIG. 6 is a flowchart showing an example of a procedure of the manufacturing process for the semiconductor device in the plasma treatment device 1 according to at least one embodiment.

As illustrated in FIG. 6, the members such as the shower head 12 and the heater pedestal 13 are installed in the chamber 11 of the plasma treatment device 1 (step S11). When the chamber is evacuated, for example, the seasoning treatment is performed inside the chamber 11 using gas similar to that used during the plasma treatment for the wafer W (step S12). Accordingly, the seasoning film Ds is formed on the members inside the chamber 11, and the atmosphere inside the chamber 11 is similar to that during the plasma treatment for the wafer W. Therefore, the generation of the particles from the members and a variation in treatment characteristics on the wafer W or the like can be prevented.

After the seasoning treatment, the temperature of the heater pedestal 13 is raised (step S13), and the plasma treatment for the wafer W is performed inside the chamber 11 that is subjected to the seasoning treatment (step S14). The plasma treatment for the wafer W is repeated until the predetermined number of treated wafers W is reached (step S16: No→step S14).

If the number of treated wafers W does not reach the predetermined number (step S15: No), it is determined whether the cycle of the plasma treatment, the dry cleaning treatment and the seasoning treatment reaches the predetermined number of times (step S16).

If the cycle reaches the predetermined number of times (step S16: Yes), the temperature of the heater pedestal 13 is lowered to a temperature lower than that during the plasma treatment (step S17). Further, the dry cleaning treatment is performed inside the chamber 11, and the deposition film Dp on the shower head 12, the heater pedestal 13 or the like is removed (step S18). At this time, the fluoride Dc is formed on the upper surface and the side surface of the heater pedestal 13.

Next, the seasoning treatment is performed inside the chamber 11, and the seasoning film Ds is formed on the shower head 12, the heater pedestal 13 and the like (step S12). The seasoning film Ds covers the fluoride Dc on the upper surface and the side surface of the heater pedestal 13. Subsequently, the temperature of the heater pedestal 13 is raised to the temperature during the plasma treatment (step S13). Thereafter, the treatments of step S14 to step S18 are further performed. Accordingly, the treatments of step S12 to step S18 are repeated until the cycle reaches the predetermined number of times.

If the cycle reaches the predetermined number of times (step S15: Yes), the treatment is ended. Thereafter, the shower head 12 and the heater pedestal 13 are uninstalled and cleaned.

Meanwhile, the wafer W subjected to the plasma treatment in the plasma treatment device 1 undergoes a plurality of treatments by another device or the like. Thereby, the semiconductor device is formed on the wafer W.

Finally, the process as the manufacturing process for the semiconductor device in the plasma treatment device 1 is ended.

### COMPARATIVE EXAMPLE

A plasma treatment device of a comparative example, for example, includes neither the side surface electrode 13s nor the side surface electrode 15s. Further, during a treatment of the plasma treatment device of the comparative example, for example, a heater pedestal is always kept at the temperature during the plasma treatment. For this reason, the following problems occur.

During a dry cleaning treatment and a seasoning treatment, the heater pedestal is kept at a high temperature during the plasma treatment. As a result, a fluoride adheres to a shower head that has a lower temperature than that of the heater pedestal. The fluoride adhering to the shower head may serve as a particle source and deteriorate the uniformity, within a plane of the wafer, of a thickness of an insulating layer formed on the wafer.

Further, since a plasma is only generated above the heater pedestal during the seasoning treatment, a seasoning film is formed on an upper surface of the heater pedestal, but the seasoning film is not formed on a side surface of the heater pedestal. Accordingly, even after the seasoning treatment is ended, the fluoride continues to sublime from the side surface of the heater pedestal and continues to be causes of the generation of the particles and the deterioration of the uniformity.

In the plasma treatment device 1 of at least one embodiment, during the dry cleaning treatment and the seasoning treatment, the temperature of the heater pedestal 13 is kept a temperature lower than that during the plasma treatment. Accordingly, even if the fluoride Dc is formed on the surface of the heater pedestal 13 by the dry cleaning treatment, sublimation of the fluoride Dc can be prevented.

In the plasma treatment device 1 of at least one embodiment, during the seasoning treatment, the plasma Ps is generated between the side surface electrode 13s and the side surface electrode 15s, and the seasoning film Ds is formed on the side surface of the heater pedestal 13 to cover the fluoride Dc. Accordingly, even if the temperature of the heater pedestal 13 is raised to the temperature during the plasma treatment after the seasoning treatment, the fluoride Dc from sublimating and adhering to the shower head 12 can be prevented.

In the plasma treatment device 1 of at least one embodiment, since the sublimation of the fluoride Dc is prevented, the generation of the particles after the dry cleaning treatment can be prevented. The deterioration of the uniformity of the thickness of the formed insulating layer within the plane of the wafer can be prevented, and stable film formation characteristics can be obtained.

In the plasma treatment device 1 of at least one embodiment, the generation time of the plasma P and the generation time of the plasma Ps during the seasoning treatment are made the same or different. Accordingly, the seasoning film Ds of a desired thickness can be formed according to the formation speed of the seasoning film Ds on the upper surface and the side surface of the heater pedestal 13. In the plasma treatment device 1 of at least one embodiment, since the high frequency power can be supplied to the shower head 12 and to the side surface electrode 15 independently, plasma generation positions (the plasma P and the plasma Ps) can be combined freely depending on occasion, and a margin of the treatment in the plasma treatment device 1 is expanded.

### MODIFICATION

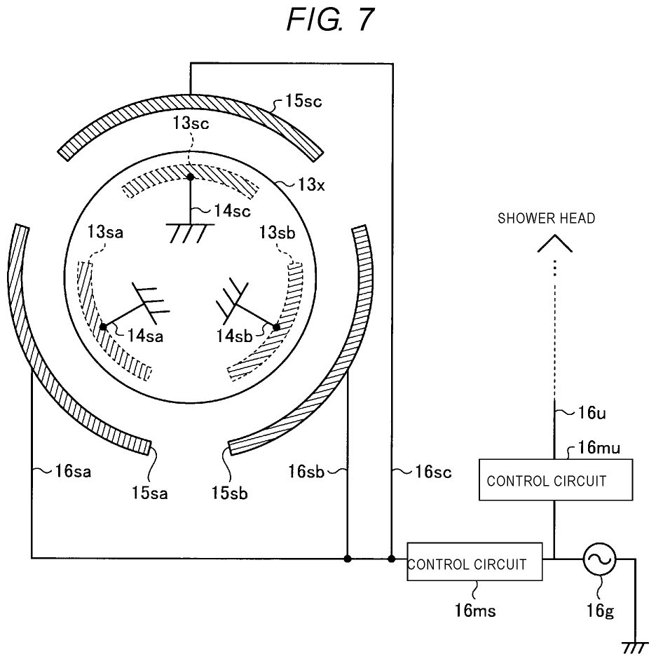

Next, with reference to FIG. 7, a plasma treatment device of a modification of at least one embodiment will be described. FIG. 7 is a cross-sectional view schematically showing a surrounding configuration of a heater pedestal 13x of the plasma treatment device according to the modification of at least one embodiment. In the plasma treatment device of the modification, shapes of side surface electrodes 13sa, 13sb, 13sc, 15sa, 15sb and 15sc are different from those of the counterparts in at least one embodiment.

As illustrated in FIG. 7, the plasma treatment device of the modification includes the plurality of divided side surface electrodes 13sa, 13sb and 13sc inside the heater pedestal 13x along an inner circumference of the heater pedestal 13x. The side surface electrodes 13sa, 13sb and 13sc are grounded via grounding wires 14sa, 14sb and 14sc, respectively.

Further, the plasma treatment device of the modification includes the plurality of divided side surface electrodes 15sa, 15sb and 15sc at an outer circumference of the heater pedestal 13x so as to surround the outer circumference of the heater pedestal 13x. The side surface electrodes 15sa, 15sb and 15sc are connected to the high frequency power source 16g via feeder lines 16sa, 16sb and 16sc, respectively.

Although FIG. 7 shows that each of the side surface electrodes is divided into three parts, that is, the side surface electrodes 13sa, 13sb and 13sc, and the side surface electrodes 15sa, 15sb and 15sc, the side surface electrodes may be divided into any number of parts. It is preferable that the divided side surface electrodes have the same size and are arranged at equal intervals.

### OTHER MODIFICATIONS

In addition to the configuration of at least one embodiment or the modification, from the end of the dry cleaning treatment to deposition of a strong deposition film Dp by the plasma treatment for a predetermined time after the seasoning treatment, an inert gas may be supplied into the chamber from the shower head during idling of the plasma treatment device. Accordingly, even if the fluoride Dc sublimes from the heater pedestal, adhesion to the shower head is prevented.

In at least one embodiment, the temperature of the heater pedestal 13 in the dry cleaning treatment and the seasoning treatment are made the same. Alternatively, the temperature of the heater pedestal during the dry cleaning treatment and that during the seasoning treatment may be different if the temperatures prevent the sublimation of the fluoride Dc.

In at least one embodiment, the plasma Ps is not generated in the vicinity of the side surface of the heater pedestal 13 during the dry cleaning treatment. However, the plasma Ps may be generated together with the plasma on the upper surface of the heater pedestal. Thereby, the deposition film Dp on the side surface of the heater pedestal can be removed more promptly. The generation time of the plasma on the upper surface of the heater pedestal and the generation time of the plasma on the side surface of the heater pedestal may be made the same or different.

In at least one embodiment, the insulating layer of SiO₂, SiN or the like is formed on the wafer W. The example of the plasma treatment is not limited thereto. On the wafer W, for example, a stacked structure of a carbon (C) layer, an insulating layer of SiO₂, SiN or the like and a Si layer, or a stacked structure of an insulating layer and a metal layer may be formed. Among them, the carbon layer may be formed using a gas such as C₅H₆, CH₄, or acetylene as a treatment gas, for example.

In at least one embodiment, NF₃ or the like is used as the cleaning gas during the dry cleaning. Alternatively, another fluorine-based gas such as SF₆, F₂, CF₄, or CHₓF_{y} may also be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma treatment device for forming a film on a substrate using plasma enhanced chemical vapor deposition, the plasma treatment device comprising:
an upper electrode;
a substrate placing table on which the substrate is to be placed, the substrate placing table including a heater configured to heat the substrate and a lower electrode opposed to the upper electrode;
a first side surface electrode that is embedded in a side surface of the substrate placing table and is spaced from the lower electrode; and
a second side surface electrode that is opposed to the first side surface electrode and is disposed outside the substrate placing table.

2. The plasma treatment device according to claim 1, further comprising:
a power source configured to apply a voltage to the upper electrode and the second side surface electrode,
wherein the power source is configured to apply the voltage to the upper electrode and to apply the voltage to the second side surface electrode independently of each other.

3. The plasma treatment device according to claim 1, wherein the upper electrode includes
a cavity configured to receive a treatment gas, and
a plurality of openings configured to discharge the treatment gas from the cavity.

4. The plasma treatment device according to claim 3, further comprising a chamber containing the upper electrode and the substrate placing table, the chamber being configured to contain the treatment gas discharge from the cavity of the upper electrode within the chamber.

5. The plasma treatment device according to claim 4, further comprising a control circuit configured to control the plurality of ejection openings and to supply the treatment gas to the upper electrode.

6. The plasma treatment device according to claim 5, wherein the control circuit is further configured to select the treatment gas from one or more treatment gas sources.

7. The plasma treatment device according to claim 6, wherein the control circuit is configured to select a cleaning gas as the treatment gas and supply the cleaning gas to the upper electrode in order to form a post-cleaning film on the substrate placing table, wherein the cleaning gas is fluoride based.

8. The plasma treatment device according to claim 7, wherein the control circuit is further configured to select a seasoning gas as the treatment gas and supply the seasoning gas to the upper electrode, wherein the seasoning gas bonds with particles inside the chamber and forms a seasoning film on the substrate placing table and the upper electrode.

9. A method for manufacturing a semiconductor device implemented by a plasma treatment device for forming a film on a substrate using plasma enhanced chemical vapor deposition,
the plasma treatment device including:
an upper electrode;
a substrate placing table on which the substrate is to be placed, the substrate placing table including a heater configured to heat the substrate and a lower electrode opposed to the upper electrode;
a first side surface electrode that is embedded in a side surface of the substrate placing table and is spaced from the lower electrode; and
a second side surface electrode that is opposed to the first side surface electrode and is disposed outside the substrate placing table,
the method comprising:
applying a voltage to the second side surface electrode to generate a plasma of a seasoning gas in the vicinity of the side surface of the substrate placing table, and
forming a seasoning film on the side surface of the substrate placing table.

10. The method for manufacturing a semiconductor device according to claim 9 further comprising:
lowering a temperature of the substrate placing table to a temperature for a seasoning treatment;
performing a dry cleaning treatment for the upper electrode and the substrate placing table using a fluorine-based gas; and
raising the temperature of the substrate placing table to a temperature for a plasma treatment,
wherein the voltage is applied to the second side surface electrode after the dry cleaning treatment and before the temperature is raised to the temperature for the plasma treatment.

11. The method for manufacturing a semiconductor device according to claim 9, further comprising:
applying a voltage to the upper electrode to generate the plasma of the seasoning gas above the substrate placing table, and
forming the seasoning film on an upper surface of the substrate placing table.

12. The method for manufacturing a semiconductor device according to claim 9, further comprising releasing the seasoning gas from the upper electrode.

13. The method for manufacturing a semiconductor device according to claim 9, further comprising:
conducting a plurality of cycles of plasma treatment to form a deposition film on the upper electrode and the substrate placing table;
dry cleaning the upper electrode and the substrate placing table to remove the deposition film; and
forming a post-cleaning film on the upper electrode and the substrate placing table.

14. The method for manufacturing a semiconductor device according to claim 13, wherein forming the seasoning film on the upper surface of the substrate placing table further comprises forming the seasoning film on the post-cleaning film.

15. A system for preventing deposition of film particles in a chamber for plasma enhanced chemical vapor deposition, the system comprising:
an upper electrode having a plurality of ejection ports configured to provide a treatment gas into the chamber;
a pedestal configured to receive a semiconductor wafer positioned beneath the upper electrode, the pedestal comprising:
a lower electrode directly below the semiconductor wafer; and
two side surface electrodes adjacent a side wall of the pedestal, wherein one of the two side surface electrodes is positioned in an interior of the pedestal and another one of the two side surface electrodes is positioned at an exterior of the pedestal; and
a control circuit operably connected to the upper electrode and the pedestal to control voltages between the upper electrode and the lower electrode and voltages between the two side surface electrodes, and to select a type of the treatment gas supplied to the upper electrode.

16. The system of claim 15, wherein the control circuit is configured to select, according to an operation stage, a deposition gas, a dry cleaning gas, or a seasoning treatment gas as the treatment gas, and wherein the seasoning treatment gas bonds particles of a previous deposition film made from the deposition gas.

17. The system of claim 16, further comprising a heater configured to heat the semiconductor wafer placed on the pedestal.

18. The system of claim 17, wherein the control circuit supplies the seasoning treatment gas to the chamber when the heater is off.

19. The system of claim 18, wherein the dry cleaning gas is fluorine-based gas, and wherein the control circuit is configured to deposit a fluoride film onto the upper electrode and the side wall of the pedestal.

20. The system of claim 19, wherein the control circuit is configured to deposit a seasoning film onto the fluoride film using the seasoning treatment gas after bonding the particles of the previous deposition film in the chamber.
